(19) United States
(12) Patent Application Publication
(10) Pub. No.: US 2022/0093657 A1
(43) Pub. Date: Mar. 24, 2022

(54) IMAGE SENSOR

(71) Applicant: SAMSUNG ELECTRONICS CO., LTD., Suwon-si (KR)

(72) Inventors: Eunyoung JO, Suwon-si (KR); Minho JANG, Suwon-si (KR); Insung JOE, Seoul (KR); Minsung HEO, Hwaseong-si (KR); Jaesung HUR, Yongin-si (KR)

(73) Assignee: SAMSUNG ELECTRONICS CO., LTD., Suwon-si (KR)

(21) Appl. No.: 17/343,062

(22) Filed: Jun. 9, 2021

(30) Foreign Application Priority Data
Sep. 24, 2020 (KR) 10-2020-0124072

(51) Int. Cl. H01L 27/146

(52) U.S. Cl. CPC H01L 27/1463; H01L 27/14621; H01L 27/14643

(57) ABSTRACT

An image sensor including a first pixel, a second pixel, a pixel isolation structure between the first pixel and the second pixel, a first rear anti-reflecting layer disposed on the first pixel, the second pixel, and the pixel isolation structure; a fence disposed on the first rear anti-reflecting layer, the fence being aligned with the pixel isolation structure; and a second rear anti-reflecting layer disposed on the first rear anti-reflecting layer and the fence, wherein an air gap is present between the first rear anti-reflecting layer and the fence, and wherein the air gap is surrounded by the second rear anti-reflecting layer.

### CROSS-REFERENCE TO RELATED APPLICATION

This application is based on and claims priority under 35 U.S.C. § 119 to Korean Patent Application No. 10-2020-0124072, filed on Sep. 24, 2020, in the Korean Intellectual Property Office, the disclosure of which is incorporated herein in its entirety by reference.

### BACKGROUND

### 1. Field

The disclosure relates to an image sensor. More particularly, the disclosure relates to a complementary metal-oxide-semiconductor (CMOS) image sensor.

### 2. Description of Related Art

An image sensor may include a plurality of pixels that are two-dimensionally arranged. Crosstalk between the pixels may reduce the resolution, sensitivity, and image quality of the image sensor. Accordingly, it is necessary to prevent the crosstalk between the pixels.

### SUMMARY

Provided are an image sensor having improved image quality.

Additional aspects will be set forth in part in the description which follows and, in part, will be apparent from the description, or may be learned by practice of the presented embodiments.

In accordance with an aspect of the disclosure, an image sensor includes a first pixel; a second pixel; a pixel isolation structure between the first pixel and the second pixel; a first rear anti-reflecting layer disposed on the first pixel, the second pixel, and the pixel isolation structure: a fence disposed on the first rear anti-reflecting layer, the fence being aligned with the pixel isolation structure; and a second rear anti-reflecting layer disposed on the first rear anti-reflecting layer and the fence, wherein an air gap is present between the first rear anti-reflecting layer and the fence, and wherein the air gap is surrounded by the second rear anti-reflecting layer.

In accordance with an aspect of the disclosure, and image sensor includes a first pixel; a second pixel spaced apart from the first pixel in a first lateral direction; a third pixel spaced apart from the first pixel in a second lateral direction; a fourth pixel spaced apart from the second pixel in the second lateral direction and spaced apart from the third pixel in the first lateral direction; a first rear anti-reflecting layer disposed on the first pixel, the second pixel, the third pixel, and the fourth pixel; a support barrier metal pattern disposed on the first rear anti-reflecting layer between the first pixel and the fourth pixel; a fence disposed on the support barrier metal pattern; and a second rear anti-reflecting layer disposed on the first rear anti-reflecting layer and the fence, wherein an air gap is present between the first rear anti-reflecting layer and the fence and, wherein the air gap is surrounded by the second rear anti-reflecting layer.

In accordance with an aspect of the disclosure, an image sensor includes a first pixel; a second pixel spaced apart from the first pixel in a first lateral direction; a third pixel spaced apart from the first pixel in a second lateral direction; a fourth pixel spaced apart from the second pixel in the second lateral direction and spaced apart from the third pixel in the first lateral direction; a pixel isolation structure between the first pixel and the second pixel, between the first pixel and the third pixel, and between the third pixel and the fourth pixel; a first aluminum oxide layer disposed on the first pixel, the second pixel, the third pixel, the fourth pixel, and the pixel isolation structure; a hafnium oxide layer disposed on the first aluminum oxide layer; a titanium pattern disposed on the hafnium oxide layer, wherein the titanium pattern extends between the first pixel and the fourth pixel; a titanium nitride layer disposed on the titanium pattern; a low refractive-index fence disposed on the titanium nitride layer; a silicon oxide layer disposed on the hafnium oxide layer and the low refractive-index fence; and a second aluminum oxide layer disposed on the silicon oxide layer, wherein an air gap is present between the hafnium oxide layer and the titanium nitride layer, wherein the air gap is surrounded by the silicon oxide layer, and wherein the air gap surrounds the titanium pattern.

### BRIEF DESCRIPTION OF THE DRAWINGS

The above and other aspects, features, and advantages of certain embodiments of the present disclosure will be more apparent from the following description taken in conjunction with the accompanying drawings in which:

FIG. 1 is a plan view of an image sensor according to an embodiment;

FIG. 2 is a cross-sectional view of an image sensor, which is taken along line A-A′ of FIG. 1, according to an embodiment;

FIG. 3 is a cross-sectional view of an image sensor, which is taken along line B-B′ of FIG. 1, according to an embodiment;

FIG. 4 is an enlarged view of region C of FIG. 3, in an image sensor according to an embodiment;

FIG. 5 is a cross-sectional view of an image sensor according to an embodiment;

FIGS. 6A to 6H are cross-sectional views of a method of manufacturing an image sensor, according to an embodiment;

FIGS. 7A and 7B are cross-sectional views of a method of manufacturing an image sensor, according to an embodiment; and

FIG. 8 is an equivalent circuit diagram of a plurality of pixels included in an image sensor, according to an embodiment.

### DETAILED DESCRIPTION

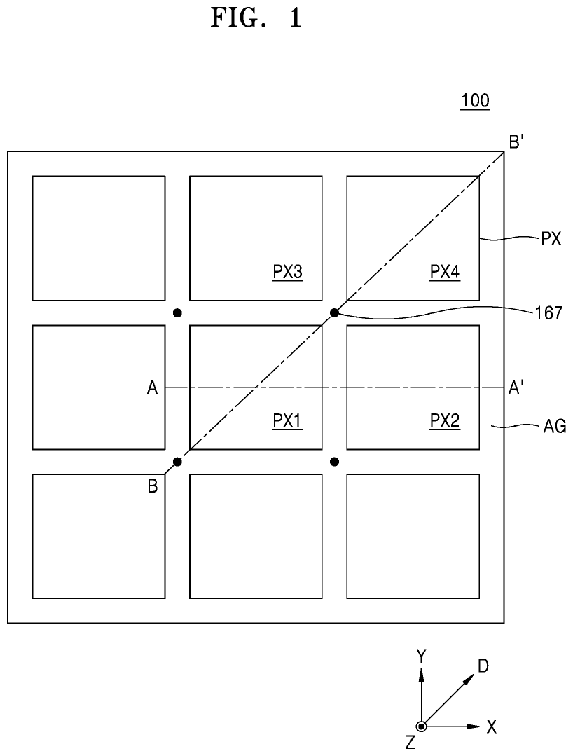

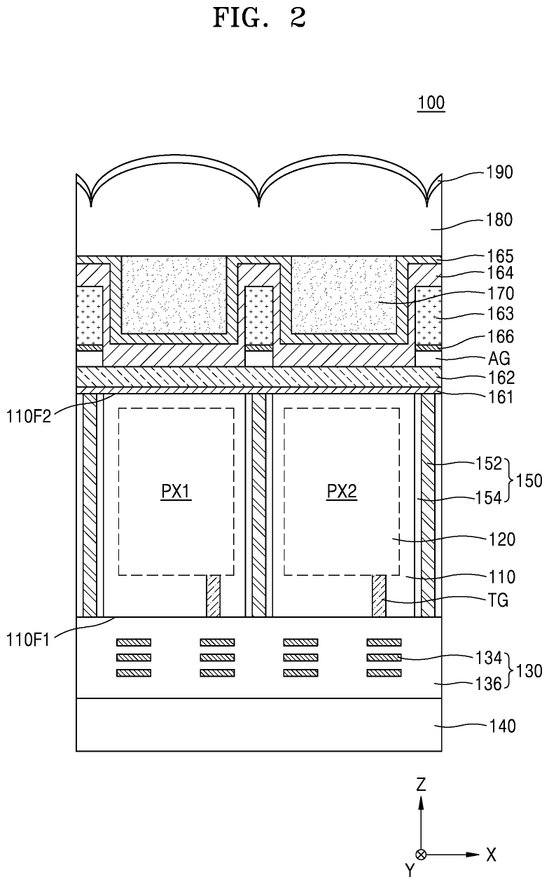

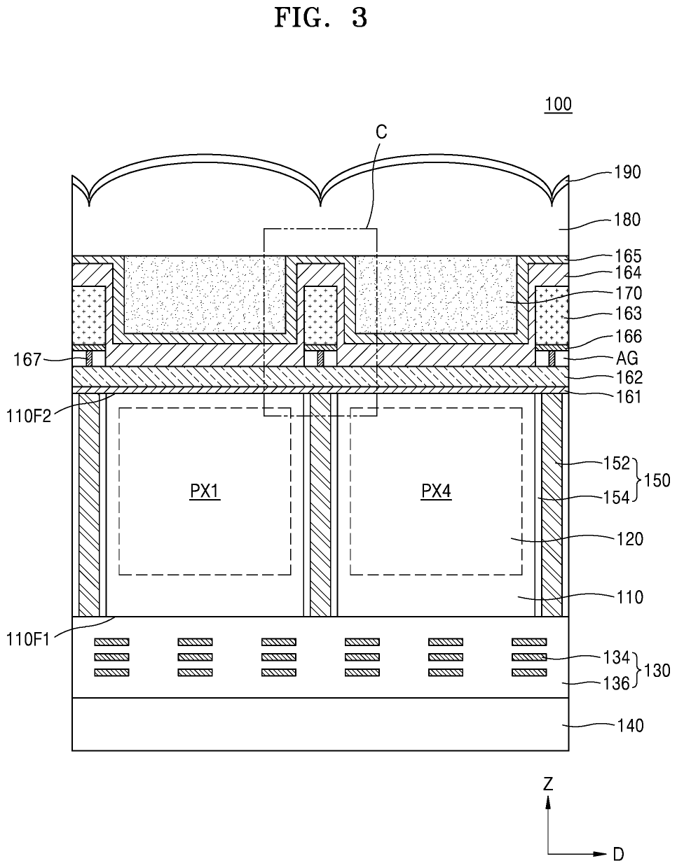

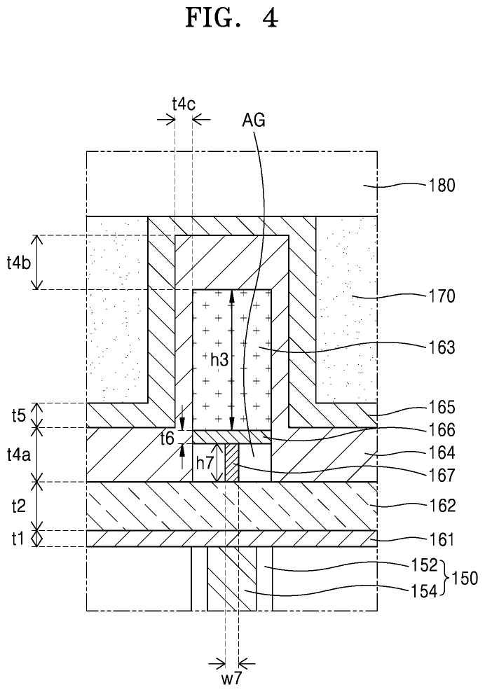

FIG. 1 is a plan view of an image sensor 100 according to an embodiment. FIG. 2 is a cross-sectional view of an image sensor, which is taken along line A-A′ of FIG. 1, according to an embodiment. FIG. 3 is a cross-sectional view of the image sensor 100, which is taken along line B-B′ of FIG. 1, according to an embodiment. FIG. 4 is an enlarged view of region C of FIG. 3, in the image sensor 100 according to an embodiment.

Referring to FIGS. 1 to 4, the image sensor 100 may include a substrate 110, a photoelectric conversion region 120, a transfer gate TG, a pixel isolation structure 150, a front side structure 130, a support substrate 140, a first rear anti-reflecting layer 162, a fence 163, a second rear anti-reflecting layer 164, an air gap AG, a support barrier metal pattern 167, a barrier metal layer 166, a third rear anti-reflecting layer 161, a passivation layer 165, a color filter 170, a microlens 180, and a capping layer 190.

The substrate 110 may include a first surface 110F1 and a second surface 110F2. In example embodiments, the substrate 110 may include a semiconductor material, such as a Group-IV semiconductor material, a Group III-V semiconductor material, or a Group II-VI semiconductor material. The Group-IV semiconductor material may include, for example, silicon (Si), germanium (Ge), or silicon germanium (SiGe). The Group III-V semiconductor material may include, for example, gallium arsenide (GaAs), indium phosphide (InP), gallium phosphide (GaP), indium arsenide (InAs), indium antimonide (InSb), or indium gallium arsenide (InGaAs). The Group II-VI semiconductor material may include, for example, zinc telluride (ZnTe) or cadmium sulfide (CdS).

The semiconductor substrate 110 may include a P-type semiconductor substrate. For example, the semiconductor substrate 110 may include a P-type silicon substrate. In example embodiments, the semiconductor substrate 110 may include a P-type bulk substrate and a P-type or N-type epitaxial (or epi) layer grown on the P-type bulk substrate. In other embodiments, the semiconductor substrate 110 may include an N-type bulk substrate and a P-type or N-type epi layer grown on the N-type bulk substrate. Alternatively, the substrate 110 may include an organic plastic substrate.

The photoelectric conversion region 120 may be in the substrate 110. The photoelectric conversion region 120 may convert a light signal into an electric signal. The photoelectric conversion region 120 may include a photodiode region and a well region, which are formed in the substrate 110. The photoelectric conversion region 120 may be an impurity region doped with impurities of a conductivity type opposite to that of the substrate 110.

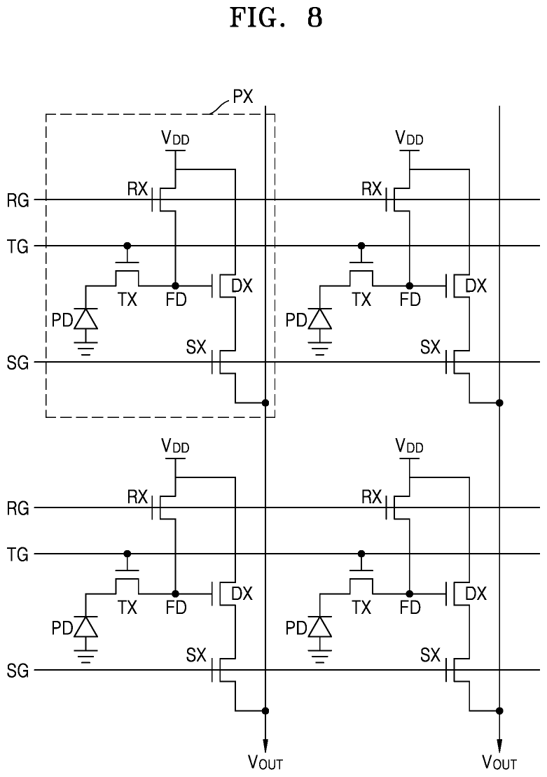

The transfer gate TG may be in the substrate 110. The transfer gate TG may extend into the substrate 110 from the first surface 110F1 of the substrate 110. The transfer gate TG may be a portion of a transfer transistor (for example TX in FIG. 8). For example, as shown in FIG. 8, the transfer transistor TX, a reset transistor RX, a drive transistor DX, and a selection transistor SX may be formed on the first surface 110F1 of the substrate 110. The transfer transistor TX may transmit charges generated by the photoelectric conversion region 120 to a floating diffusion region FD. The reset transistor RX may periodically reset the charges stored in the floating diffusion region FD. The drive transistor DX may serve as a source-follower buffer amplifier and buffer a signal corresponding to the charges stored in the floating diffusion region FD. The selection transistor SX may perform switching and addressing operations to select a plurality of pixels PX.

An active region and a device isolation film defining the floating diffusion region FD may be further formed on the first surface 110F1 of the substrate 110.

The photoelectric conversion region 120, the transfer gate TG, a plurality of transistors, and the floating diffusion region FD may form a pixel PX. Hereinafter, components of the pixel PX will be described in further detail with reference to FIG. 8.

The plurality of pixels PX may be two-dimensionally arranged. For example, a second pixel PX2 may be apart from a first pixel PX1 in a first direction (X direction), and a third pixel PX3 may be apart from the first pixel PX1 in a second direction (Y direction). A fourth pixel PX4 may be apart from the first pixel PX1 in a diagonal direction (D direction), apart from the second pixel PX2 in the second direction (Y direction), and apart from the third pixel PX3 in the first direction (X direction). In some embodiments, the first direction (X direction) may be perpendicular to the second direction (Y direction). In some embodiments, the diagonal direction (D direction) may be at an angle with respect to the first direction (X direction) and the second direction (Y direction). In some embodiments, the diagonal direction (D direction) may be at an angle of 45° with respect to the first direction (X direction) and the second direction (Y direction). However, in other embodiments, the diagonal direction (D direction) may be at different angles with respect to the first direction (X direction) and the second direction (Y direction).

The pixel isolation structure 150 may pass through the substrate 110 and electrically isolate one pixel PX from another pixel PX adjacent thereto. For example, the pixel isolation structure 150 may physically and electrically isolate the first pixel PX1 from the second pixel PX2 and physically and electrically isolate the first pixel PX1 from the fourth pixel PX4. In a view from above, the pixel isolation structure 150 may have a mesh shape or a grid shape. That is, the pixel isolation structure 150 may extend among the plurality of pixels PX. For example, the pixel isolation structure 150 may extend between the first pixel PX1 and the second pixel PX2, between the first pixel PX1 and the third pixel PX3, between the second pixel PX2 and the fourth pixel PX4, and between the third pixel PX3 and the fourth pixel PX4. As shown in FIG. 2, the pixel isolation structure 150 may extend from the first surface 110F1 of the substrate 110 to the second surface 110F2 thereof.

The pixel isolation structure 150 may include a conductive layer 152 and an insulating liner 154. Each of the conductive layer 152 and the insulating liner 154 may pass through the substrate 110 from the first surface 110F1 of the substrate 110 to the second surface 110F2 thereof. The insulating liner 154 may be between the substrate 110 and the conductive layer 152 and electrically isolate the conductive layer 152 from the substrate 110. In example embodiments, the conductive layer 152 may include a conductive material, such as polysilicon or a metal. The insulating liner 154 may include a metal oxide, such as hafnium oxide, aluminum oxide, and tantalum oxide. In this case, the insulating liner 154 may serve as a negative fixed charge layer. In other embodiments, the insulating liner 154 may include an insulating material, such as silicon oxide, silicon nitride, and silicon oxynitride.

The front side structure 130 may be on the first surface 110F1 of the substrate 110. In embodiments, when a first element is described as “on” a second element, this may mean that the first element is arranged or disposed directly or indirectly on the second element. For example, the first element may be disposed directly on the second element, or one or more other elements may be located between the first element and the second element. The front side structure 130 may include interconnection layers 134 and an insulating layer 136. The insulating layer 136 may electrically isolate the interconnection layers 134 from each other on the first surface 110F1 of the substrate 110.

The interconnection layers 134 may be electrically connected to transistors on the first surface 110F1 of the substrate 110. The interconnection layers 134 may include tungsten, aluminum, copper, tungsten silicide, titanium silicide, tungsten nitride, titanium nitride, or doped polysilicon. The insulating layer 136 may include an insulating material, such as silicon oxide, silicon nitride, silicon oxynitride, and a low-k material. The low-k material may include, for example, at least one of flowable oxide (FOX), torene silazene (TOSZ), undoped silica glass (USG), borosilica glass (BSG), phosphosilica glass (PSG), borophosphosilica glass (BPSG), plasma-enhanced tetra ethyl ortho silicate (PETEOS), fluoride silicate glass (FSG), carbon doped silicon oxide (CDO), Xerogel, Aerogel, amorphous fluorinated carbon, organo silicate glass (OSG), parylene, bis-benzocyclobutenes (BCB), SiLK, polyimide, a porous polymeric material, and a combination thereof, without being limited thereto.

In embodiments, the support substrate 140 may be on the front side structure 130. An adhesive member may be further between the support substrate 140 and the front side structure 130.

The first rear anti-reflecting layer 162 may be on the second surface 110F2 of the substrate 110. That is, the first rear anti-reflecting layer 162 may be on all the pixels PX and the pixel isolation structure 150. In some embodiments, the first rear anti-reflecting layer 162 may include hafnium oxide. In another embodiment, the first rear anti-reflecting layer 162 may include silicon nitride (SiN), aluminum oxide (Al₂O₃), zirconium oxide (ZrO₂), tantalum oxide (Ta₂O₅), titanium oxide (TiO₂), lanthanum oxide (La₂O₃), praseodymium oxide (Pr₂O₃), cerium oxide (CeO₂), neodymium oxide (Nd₂O₃), promethium oxide (Pm₂O₃), samarium oxide (Sm₂O₃), europium oxide (Eu₂O₃), gadolinium oxide (Gd₂O₃), terbium oxide (Tb₂O₃), dysprosium oxide (Dy₂O₃), holmium oxide (Ho₂O₃), thulium oxide (Tm₂O₃), ytterbium oxide (Yb₂O₃), lutetium oxide (Lu₂O₃), or yttrium oxide (Y₂O₃). In some embodiments, a thickness t2 of the first rear anti-reflecting layer 162 may be in a range of about 50 nm to about 100 nm.

The fence 163 may be on the first rear anti-reflecting layer 162. In a view from above, the fence 163 may overlap the pixel isolation structure 150. That is, in the view from above, the fence 163 may extend between the pixels PX. For example, in the view from above, the fence 163 may extend between the first pixel PX1 and the second pixel PX2, between the first pixel PX1 and the third pixel PX3, between the second pixel PX2 and the fourth pixel PX4, and between the third pixel PX3 and the fourth pixel PX4. In some embodiments, a height h3 of the fence 163 may be in a range of about 320 nm to about 370 nm.

In some embodiments, the fence 163 may include a low refractive-index material. For example, the low refractive-index material may have a refractive index greater than about 1.0 and less than or equal to about 1.4. In example embodiments, the low refractive-index material may include polymethylmetacrylate (PMMA), silicon acrylate, cellulose acetatebutyrate (CAB), silica, or fluoro-silicon acrylate (FSA). For example, the low refractive-index material may include a polymer material in which silica (SiOₓ) particles are dispersed.

When the fence 163 includes a low refractive-index material having a relatively low refractive index, light incident toward the fence 163 may be totally reflected and directed toward a central portion of the pixel PX. The fence 163 may prevent light, which is obliquely incident on the color filter 170 located on one pixel PX, from entering the color filter 170 located on another pixel PX adjacent thereto. Thus, crosstalk between the plurality of pixels PX may be prevented.

The second rear anti-reflecting layer 164 may be on the first rear anti-reflecting layer 162 and the fence 163. That is, the second rear anti-reflecting layer 164 may cover the first rear anti-reflecting layer 162 and the fence 163. Specifically, the second rear anti-reflecting layer 164 may be on an upper surface of the first rear anti-reflecting layer 162, a side surface of the fence 163, and an upper surface of the fence 163. A thickness t4a of the second rear anti-reflecting layer 164 on the first rear anti-reflecting layer 162 may be greater than a thickness t4c of the second rear anti-reflecting layer 164 on the side surface of the fence 163. Also, a thickness t4b of the second rear anti-reflecting layer 164 on the top surface of the fence 163 may be greater than the thickness t4c of the second rear anti-reflecting layer 164 on the side surface of the fence 163. For example, the thickness t4a of the second rear anti-reflecting layer 164 on the first rear anti-reflecting layer 162 may be in a range of about 65 nm to about 75 nm, and the thickness t4b of the second rear anti-reflecting layer 164 on the upper surface of the fence 163 may be in a range of about 50 nm to about 100 nm. The thickness t4c of the second rear anti-reflecting layer 164 on the side surface of the fence 163 may be in a range of about 5 nm to about 30 nm.

In some embodiments, the second rear anti-reflecting layer 164 may include silicon oxide. In another embodiment, the second rear anti-reflecting layer 164 may include silicon nitride (SiN), hafnium oxide (HfO₂), aluminum oxide (Al₂O₃), zirconium oxide (ZrO₂), tantalum oxide (Ta₂O₅), titanium oxide (TiO₂), lanthanum oxide (La₂O₃), praseodymium oxide (Pr₂O₃), cerium oxide (CeO₂), neodymium oxide (Nd₂O₃), promethium oxide (Pm₂O₃), samarium oxide (Sm₂O₃), europium oxide (Eu₂O₃), gadolinium oxide (Gd₂O₃), terbium oxide (Tb₂O₃), dysprosium oxide (Dy₂O₃), holmium oxide (Ho₂O₃), thulium oxide (Tm₂O₃), ytterbium oxide (Yb₂O₃), lutetium oxide (Lu₂O₃), or yttrium oxide (Y₂O₃).

The air gap AG may be between the first rear anti-reflecting layer 162 and the fence 163 and surrounded by the second rear anti-reflecting layer 164. In a view from above, the air gap AG may overlap the fence 163. That is, in the view from above, the air gap AG may extend between the pixels PX. For example, in the view from above, the air gap AG may extend between the first pixel PX1 and the second pixel PX2, between the first pixel PX1 and the third pixel PX3, between the second pixel PX2 and the fourth pixel PX4, and between the third pixel PX3 and the fourth pixel PX4.

The air gap AG may have a low refractive index. Accordingly, light incident toward the air gap AG may be totally reflected and reflected toward a central portion of the pixel PX. The air gap AG may prevent light, which is incident at an inclination angle on the color filter 170 located on one pixel PX, from entering the color filter 170 located on another pixel PX adjacent thereto. Thus, crosstalk between the plurality of pixels PX may be prevented.

The support barrier metal pattern 167 may be between the first rear anti-reflecting layer 162 and the fence 163. In a view from above, the support barrier metal pattern 167 may be between two pixels PX which neighbor in the diagonal direction D, for example the first pixel PX1 and the fourth pixel PX4. In other words, the support barrier metal pattern 167 may be present between the second pixel PX2 and the third pixel PX3. In the view from above, the support barrier metal pattern 167 may not be present between two pixels PX which neighbor in the first direction (X direction), for example the first pixel PX1 and the second pixel PX2. In addition, in the view from above, the support barrier metal pattern 167 may not be present between two pixels PX which neighbor in the second direction (Y direction), for example the first pixel PX1 and the third pixel PX3.

The support barrier metal pattern 167 may support the fence 163 and maintain the air gap AG between the fence 163 and the first rear anti-reflecting layer 162. In some embodiments, the support barrier metal pattern 167 may include a barrier metal, such as titanium. The support barrier metal pattern 167 may form a charge transfer path and prevent the occurrence of a bruise defect.

In some embodiments, a width w7 of the support barrier metal pattern 167 may be in a range of about 5 nm to about 10 nm. When the width w7 of the support barrier metal pattern 167 is less than about 5 nm, the support barrier metal pattern 167 may not sufficiently support the fence 163. When the width w7 of the support barrier metal pattern 167 exceeds about 10 nm, a thickness of the air gap AG around the support barrier metal pattern 167 may be reduced, and thus, crosstalk between the pixels PX may increase. In some embodiments, a height h7 of the support barrier metal pattern 167 may be in a range of about 50 nm to about 70 nm.

The barrier metal layer 166 may be on a lower surface of the fence 163. Specifically, the barrier metal layer 166 may be between the fence 163 and the air gap AG. That is, the barrier metal layer 166 may be between the fence 163 and the support barrier metal pattern 167. In some embodiments, the barrier metal layer 166 may include a barrier metal, such as titanium nitride. In some embodiments, a thickness t6 of the barrier metal layer 166 may be in a range of about 5 nm to about 15 nm.

The third rear anti-reflecting layer 161 may be between the first rear anti-reflecting layer 162 and the pixels PX and between the first rear anti-reflecting layer 162 and the pixel isolation structure 150. That is, the third rear anti-reflecting layer 161 may be between the first rear anti-reflecting layer 162 and the substrate 110. In some embodiments, the third rear anti-reflecting layer 161 may include, for example, aluminum oxide. In another embodiment, the third rear anti-reflecting layer 161 may include silicon nitride (SiN), hafnium oxide (HfO₂), zirconium oxide (ZrO₂), tantalum oxide (Ta₂O₅), titanium oxide (TiO₂), lanthanum oxide (La₂O₃), praseodymium oxide (Pr₂O₃), cerium oxide (CeO₂), neodymium oxide (Nd₂O₃), promethium oxide (Pm₂O₃), samarium oxide (Sm₂O₃), europium oxide (Eu₂O₃), gadolinium oxide (Gd₂O₃), terbium oxide (Tb₂O₃), dysprosium oxide (Dy₂O₃), holmium oxide (Ho₂O₃), thulium oxide (Tm₂O₃), ytterbium oxide (Yb₂O₃), lutetium oxide (Lu₂O₃), or yttrium oxide (Y₂O₃). A thickness t1 of the third rear anti-reflecting layer 161 may be in a range of, for example, about 5 nm to about 20 nm.

The passivation layer 165 may be on the second rear anti-reflecting layer 164. The passivation layer 165 may protect the second rear anti-reflecting layer 164, the first rear anti-reflecting layer 162, and the fence 163. In some embodiments, the passivation layer 165 may include aluminum oxide. In some embodiments, a thickness t5 of the passivation layer 165 may be in a range of about 5 nm to about 20 nm.

A plurality of color filters 170 may be on the passivation layer 165 and isolated from each other by the fence 163. The plurality of color filters 170 may include, for example, a combination of green filters, blue filters, and red filters. In another embodiment, the plurality of color filters 170 may include, for example, a combination of cyan, magenta, and yellow filters.

The microlens 180 may be on the color filter 170 and the passivation layer 165. In a view from above, the microlens 180 may be disposed to correspond to the pixel PX. The microlens 180 may be transparent. For example, the microlens 180 may have a transmittance of about 90% or higher with respect to light in a visible light range. The light in the visible light range may have a wavelength of about 380 nm to about 770 nm. The microlens 180 may include, for example, a resin-based material, such as a styrene-based resin, an acrylic resin, a styrene-acryl copolymer resin, or a siloxane-based resin. The microlens 180 may condense incident light, and the condensed light may be incident on the photoelectric conversion region 120 through the color filter 170. The capping layer 190 may be on the microlens 180.

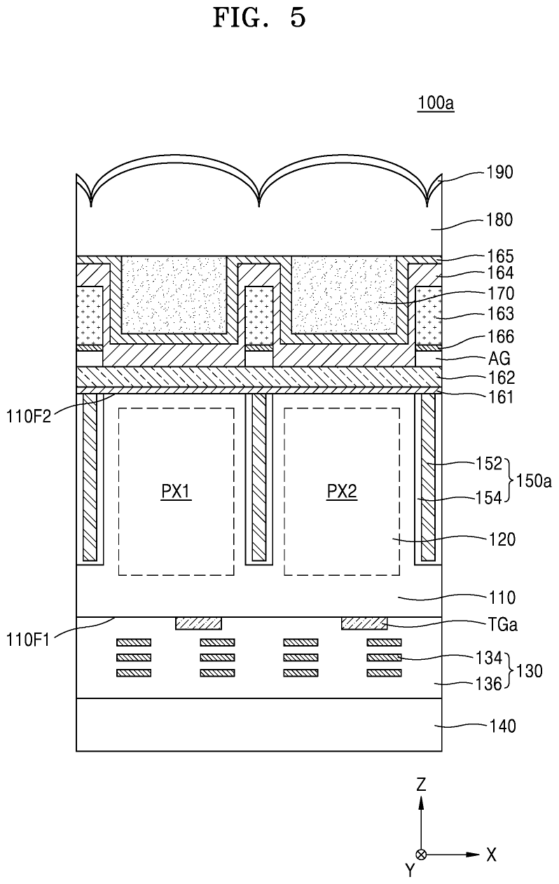

FIG. 5 is a cross-sectional view of an image sensor 100a according to an embodiment. Hereinafter, differences between the image sensor 100 described with reference to FIGS. 1 to 4 and the image sensor 100a shown in FIG. 5 will be described.

Referring to FIG. 5, the image sensor 100a may include a pixel isolation structure 150a instead of the pixel isolation structure 150 in FIG. 2. The pixel isolation structure 150a may not completely pass through a substrate 110. Specifically, although the pixel isolation structure 150a extends into the substrate 110 from a second surface 110F2 of the substrate 110, the pixel isolation structure 150a may not reach a first surface 110F1 of the substrate 110.

In addition, the image sensor 100a may include a transfer gate TGa instead of the transfer gate TG in FIG. 2. The transfer gate TGa may be formed on the first surface 110F1 of the substrate 110 and may not be formed in a recess of the substrate 110.

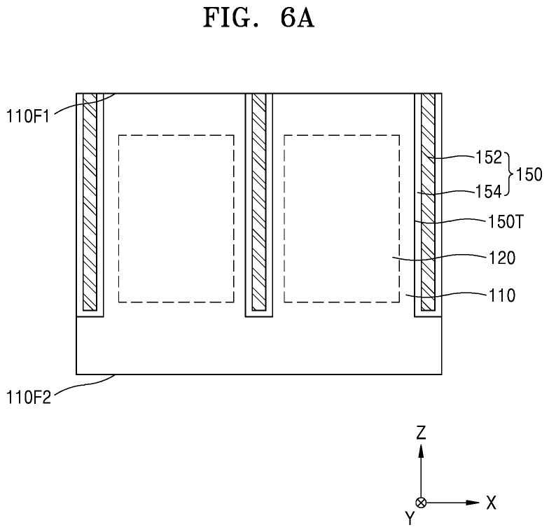

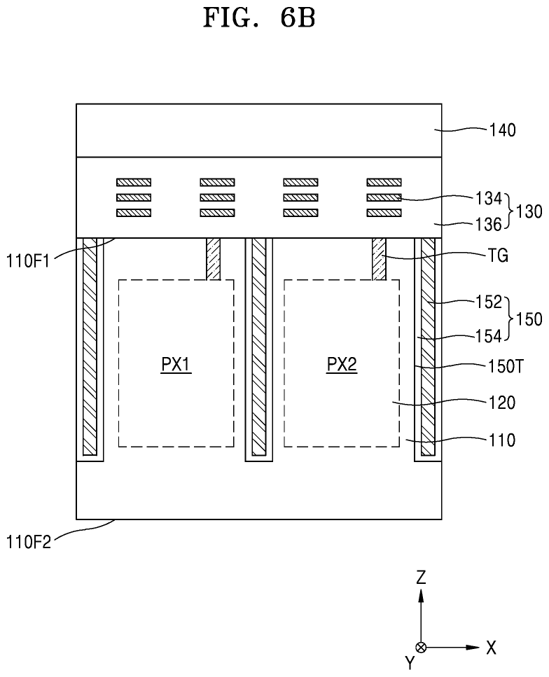

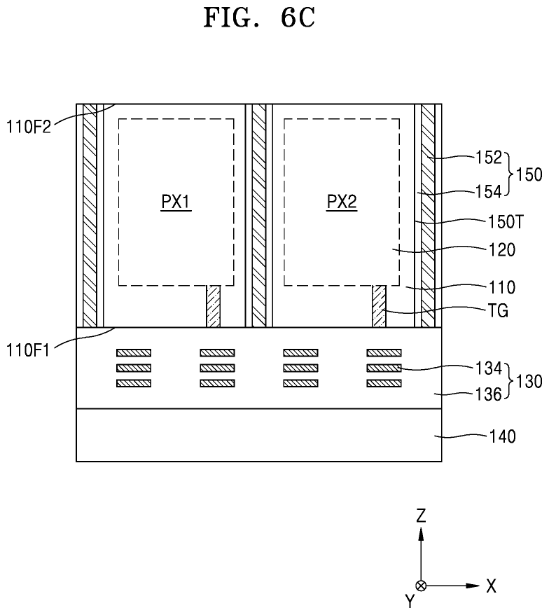

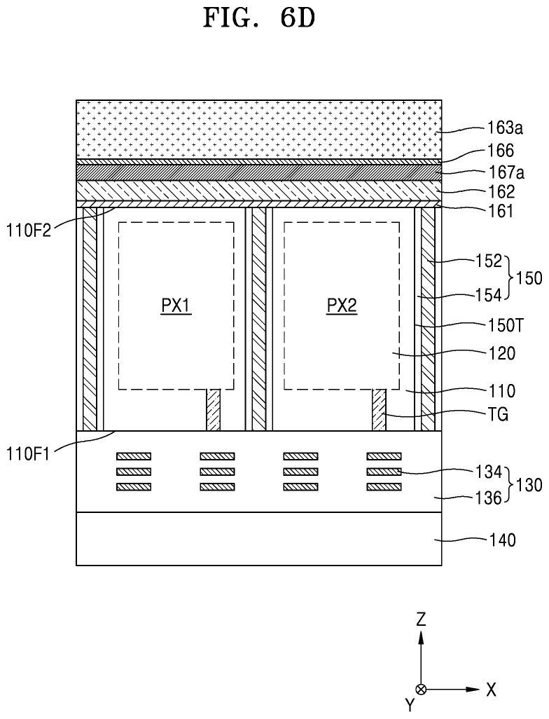

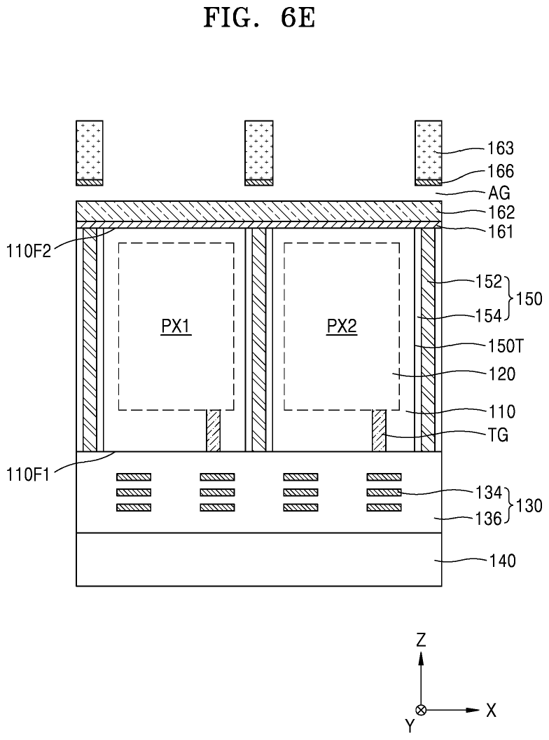

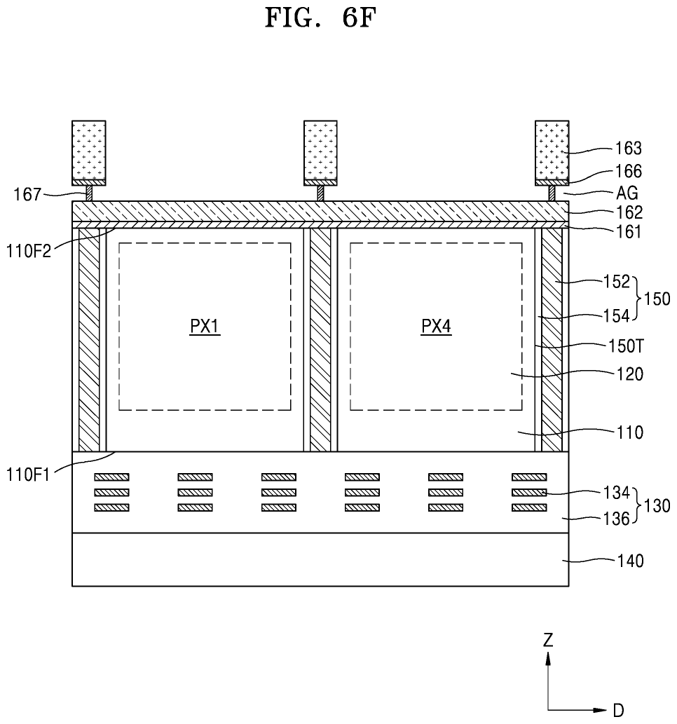

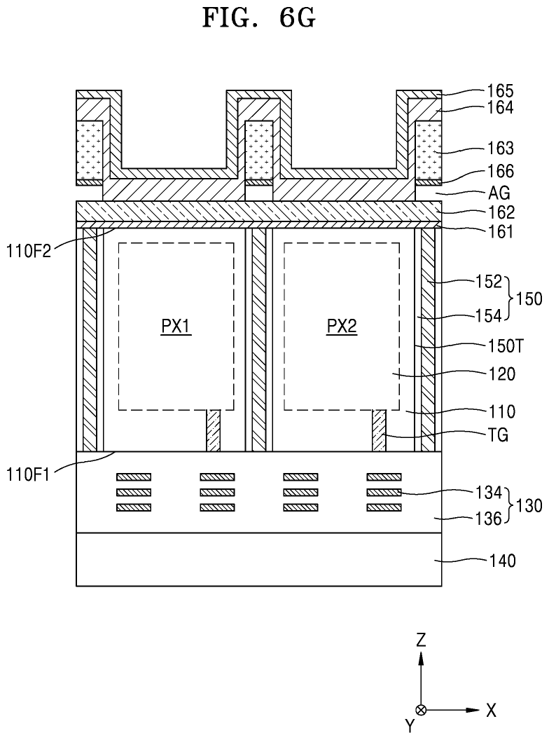

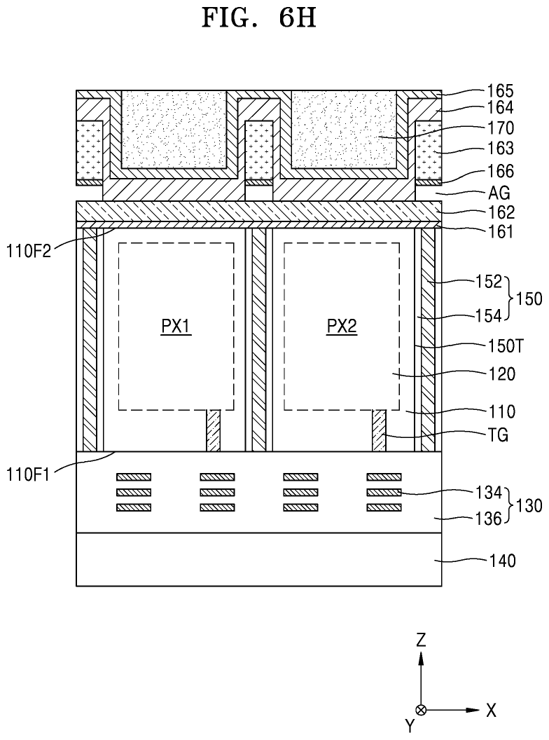

FIGS. 6A to 6H are cross-sectional views of a method of manufacturing an image sensor, according to an embodiment. FIGS. 6A to 6E, 6G, and 6H are cross-sectional views corresponding to a cross-sectional view taken along line A-A′ of FIG. 1, and FIG. 6F is a cross-sectional view corresponding to a cross-sectional view taken along line B-B′ of FIG. 1.

Referring to FIG. 6A, a substrate 110 having a first surface 110F1 and a second surface 110F2, which are opposite to each other, may be prepared. A mask pattern may be formed on the first surface 110F1 of the substrate 110, and a portion of the substrate 110 may be removed from the first surface 110F of the substrate 110 by using the mask pattern to form a trench 150T.

Subsequently, an insulating liner 154 and a conductive layer 152 may be sequentially formed inside the trench 150T and on the first surface 110F1 of the substrate 110. Portions of the insulating liner 154 and the conductive layer 152 on the first surface 110F1 of the substrate 110 may be removed using a planarization process, and thus, a pixel isolation structure 150 may be formed inside the trench 150T.

Thereafter, an ion implantation process may be performed on the first surface 110F1 of the substrate 110, thereby forming a photoelectric conversion region 120 including a photodiode region and a well region. For example, the photodiode region may be formed by doping N-type impurities, while the well region may be formed by doping P-type impurities.

Referring to FIG. 6B, a transfer gate TG, which extends into the substrate 110 from the first surface 110F1 of the substrate 110, may be formed. An ion implantation process may be performed on a partial region of the first surface 110F1 of the substrate 110, thereby forming a floating diffusion region and an active region. Thus, pixels PX1 and PX2 may be formed.

Next, a front side structure 130 may be formed on the first surface 110F1 of the substrate 110. Operations of forming a conductive layer on the first surface 110F1 of the substrate 110, patterning the conductive layer, and forming an insulating layer to cover the patterned conductive layer may be repeatedly performed, and thus, interconnection layers 134 and an insulating layer 136 may be formed on the substrate 110. Thereafter, a support substrate 140 may be adhered to the insulating layer 136.

Referring to FIG. 6C, the substrate 110 may be turned upside down such that the second surface 110F2 of the substrate 110 faces upward. Next, a portion of the substrate 110 may be removed from the second surface 110F2 of the substrate 110 by using a planarization process, such as a chemical mechanical polishing (CMP) process or an etchback process, so that the conductive layer 152 may be exposed. Due to the removal process, a level of the second surface 110F2 of the substrate 110 may be reduced. In this case, one pixel PX surrounded by the pixel isolation structure 150 may be physically and electrically isolated from another pixel PX adjacent thereto.

Referring to FIG. 6D, a third rear anti-reflecting layer 161, a first rear anti-reflecting layer 162, a support barrier metal layer 167a, a barrier metal layer 166, and a fence layer 163a may be sequentially formed on the second surface 110F2 of the substrate 110. In some embodiments, the third rear anti-reflecting layer 161 may include aluminum oxide, and the first rear anti-reflecting layer 162 may include hafnium oxide. The support barrier metal layer 167a may include titanium, the barrier metal layer 166 may include titanium nitride, and the fence layer 163a may include a low refractive-index material.

Referring to FIGS. 6D to 6F, the fence layer 163a may be patterned. For example, a mask may be formed on the fence layer 163a, and the fence layer 163a may be selectively etched to form a fence 163. Next, the barrier metal layer 166 may be patterned using the fence 163 as an etch mask. Thereafter, the support barrier metal layer 167a may be etched using the fence 163 as an etch mask, thereby forming a support barrier metal pattern 167. Although the fence 163 is used as the etch mask, an air gap AG may be formed between the first rear anti-reflecting layer 162 and the barrier metal layer 166 by over-etching the support barrier metal layer 167a. The air gap AG may reduce crosstalk.

As shown in FIG. 6E, due to the over-etching process, the support barrier metal pattern 167 may not remain between two pixels PX1 and PX2, which neighbor in a first direction (X direction), and a space between the pixels PX1 and PX2 that neighbor in the first direction (X direction) may be filled with the air gap AG. However, as shown in FIG. 6F, an etching time may be adjusted such that the support barrier metal pattern 167 remains between two pixels PX1 and PX4, which neighbor in a diagonal direction (D direction). The remaining support barrier metal pattern 167 may reduce a bruise defect.

The first rear anti-reflecting layer 162, which includes hafnium oxide, may serve as an etch stop layer during the etching of the support barrier metal layer 167a. Accordingly, because there is no need to form an additional etch stop layer, a manufacturing process may be simplified, and manufacturing costs and time may be reduced.

Referring to FIG. 6G, a second rear anti-reflecting layer 164 may be formed on the first rear anti-reflecting layer 162 and the fence 163. The second rear anti-reflecting layer 164 may surround the air gap AG. In some embodiments, the second rear anti-reflecting layer 164 may include silicon oxide. The second rear anti-reflecting layer 164 may be formed using a deposition process having high straightness, such as an evaporation process. Accordingly, as described with reference to FIG. 4, a thickness t4a of the second rear anti-reflecting layer 164 formed on the first rear anti-reflecting layer 162 may be greater than a thickness t4c of the second rear anti-reflecting layer 164 on a side surface of the fence 163, and a thickness t4b of the second rear anti-reflecting layer 164 on an upper surface of the fence 163 may be greater than the thickness t4c of the second rear anti-reflecting layer 164 on the side surface of the fence 163.

Next, a passivation layer 165 may be formed on the second rear anti-reflecting layer 164. In some embodiments, the passivation layer 165 may include aluminum oxide.

Referring to FIG. 6H, a color filter 170 may be formed on the passivation layer 165.

Referring to FIG. 2, a microlens 180 may be formed on the color filter 170 and the passivation layer 165. For example, a microlens material layer may be formed on the color filter 170 and the passivation layer 165, and a mask pattern may be formed on the microlens material layer. Thereafter, the mask pattern may be transformed into a hemispherical shape by performing a reflow process. In example embodiments, the reflow process may be performed at a temperature of about 100° C. to about 200° C. for several seconds to several tens of minutes, without being limited thereto. Next, the microlens material layer may be etched using the mask pattern as an etch mask, thereby forming the microlens 180.

Subsequently, a capping layer 190 may be formed on the microlens 180. As a result, the manufacture of the image sensor 100 shown in FIG. 2 may be completed.

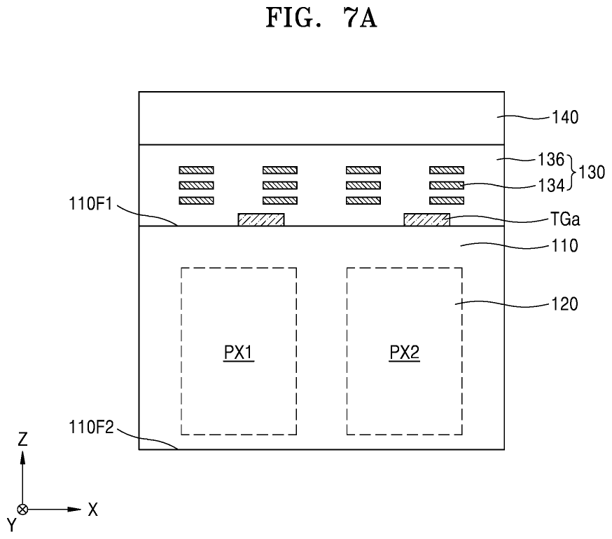

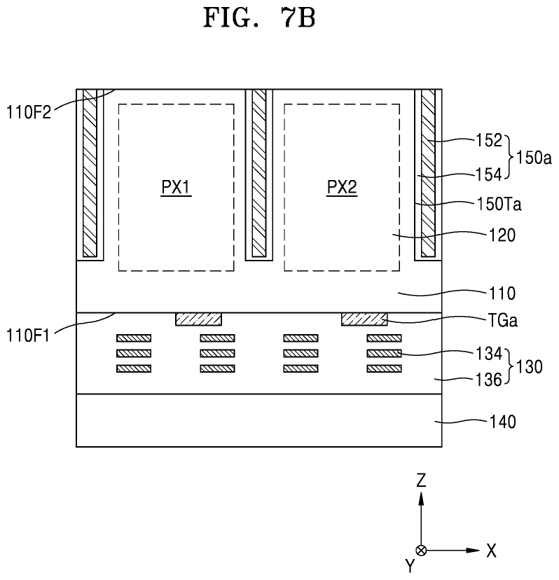

FIGS. 7A and 7B are cross-sectional views of a method of manufacturing an image sensor, according to an embodiment.

Referring to FIG. 7A, an ion implantation process may be performed on a first surface 110F1 of a substrate 110, thereby forming a photoelectric conversion region 120 including a photodiode region and a well region. For example, the photodiode region may be formed by doping N-type impurities, and the well region may be formed by doping P-type impurities.

A transfer gate TGa may be formed on the first surface 110F1 of the substrate 110, and an ion implantation process may be performed on a partial region of the first surface 110F1 of the substrate 110, thereby forming a floating diffusion region and an active region. Thus, pixels PX1 and PX2 may be formed.

Next, a front side structure 130 may be formed on the first surface 110F1 of the substrate 110. Operations of forming a conductive layer on the first surface 110F1 of the substrate 110, patterning the conductive layer, and forming an insulating layer to cover the patterned conductive layer may be repeatedly performed, and thus, interconnection layers 134 and an insulating layer 136 may be formed on the substrate 110. Thereafter, a support substrate 140 may be adhered to the insulating layer 136.

Referring to FIG. 7B, the substrate 110 may be turned upside down such that a second surface 110F2 of the substrate 110 faces upward. A mask pattern may be formed on the second surface 110F2 of the substrate 110, and a portion of the substrate 110 may be removed from the second surface 110F2 of the substrate 110 by using the mask pattern, thereby forming a trench 150Ta.

Subsequently, an insulating liner 154 and a conductive layer 152 may be sequentially formed inside the trench 150Ta and on the second surface 110F2 of the substrate 110. Portions of the insulating liner 154 and the conductive layer 152 on the second surface 110F2 of the substrate 110 may be removed using a planarization process, and thus, a pixel isolation structure 150a may be formed inside the trench 150Ta.

Thereafter, operations described with reference to FIGS. 2 and 6A to 6H may be performed, and thus, a third rear anti-reflecting layer 161, a first rear anti-reflecting layer 162, an air gap AG, a support barrier metal pattern 167, a barrier metal layer 166, a fence 163, a second rear anti-reflecting layer 164, a passivation layer 165, a color filter 170, a microlens 180, and a capping layer 190 may be formed. As a result, the manufacture of the image sensor 100a shown in FIG. 5 may be completed.

FIG. 8 is an equivalent circuit diagram of a plurality of pixels PX included in an image sensor according to an embodiment.

Referring to FIG. 8, the plurality of pixels PX may be arranged in a matrix form. Each of the plurality of pixels PX may include a transfer transistor TX and logic transistors RX, SX, and DX. Here, the logic transistors may include a reset transistor RX, selection transistor SX, and a drive transistor DX (or a source-follower transistor). The reset transistor RX may include a reset gate RG, the selection transistor SX may include a selection gate SG, and the transfer transistor TX may include a transfer gate TG.

Each of the plurality of pixels PX may further include a photoelectric conversion element PD and a floating diffusion region FD. The photoelectric conversion element PD may correspond to the photoelectric conversion region 120 described with reference to FIGS. 3 to 6. The photoelectric conversion element PD may generate and accumulate charges in proportion to the quantity of light incident from the outside and include a photodiode, a phototransistor, a photogate, a pinned photodiode (PPD), or a combination thereof.

The transfer gate TG may transmit the charges generated in the photoelectric conversion element PD to the floating diffusion region FD. The floating diffusion region FD may receive the charges generated in the photoelectric conversion element PD and cumulatively store the charges. The drive transistor DX may be controlled according to the quantity of the charges accumulated in the floating diffusion region FD.

The reset transistor RX may periodically reset the charges accumulated in the floating diffusion region FD. A drain electrode of the reset transistor RX may be connected to the floating diffusion region FD, and a source electrode thereof may be connected to a power supply voltage VDD. When the reset transistor RX is turned on, the power supply voltage VDD connected to the source electrode of the reset transistor RX may be transmitted to the floating diffusion region FD. When the reset transistor RX is turned on, the charges accumulated in the floating diffusion region FD may be emitted, and thus, the floating diffusion region FD may be reset.

The drive transistor DX may be connected to a current source located outside the plurality of pixels PX and serve as a source-follower buffer amplifier. The drive transistor DX may amplify a potential change at the floating diffusion region FD and output the amplified potential change to an output line VOUT.

The selection transistor SX may select the plurality of pixels PX by a unit of one row. When the selection transistor SX is turned on, the power supply voltage VDD may be transmitted to a source electrode of the drive transistor DX.

While embodiments have been particularly shown and described, it will be understood that various changes in form and details may be made therein without departing from the spirit and scope of the following claims.

What is claimed is:

1. An image sensor comprising:
a first pixel;
a second pixel;
a pixel isolation structure between the first pixel and the second pixel;
a first rear anti-reflecting layer disposed on the first pixel, the second pixel, and the pixel isolation structure;
a fence disposed on the first rear anti-reflecting layer, the fence being aligned with the pixel isolation structure; and
a second rear anti-reflecting layer disposed on the first rear anti-reflecting layer and the fence,
wherein an air gap is present between the first rear anti-reflecting layer and the fence, and
wherein the air gap is surrounded by the second rear anti-reflecting layer.

2. The image sensor of claim 1, wherein the fence comprises a low refractive-index material.

3. The image sensor of claim 1, wherein the first rear anti-reflecting layer comprises hafnium oxide, and the second rear anti-reflecting layer comprises silicon oxide.

4. The image sensor of claim 1, wherein the air gap overlaps the fence.

5. The image sensor of claim 1, further comprising a barrier metal layer disposed on a lower surface of the fence.

6. The image sensor of claim 5, wherein the barrier metal layer comprises titanium nitride.

7. The image sensor of claim 1, further comprising a third rear anti-reflecting layer between the first pixel and the first rear anti-reflecting layer, between the second pixel and the first rear anti-reflecting layer, and between the pixel isolation structure and the first rear anti-reflecting layer.

8. The image sensor of claim 7, wherein the third rear anti-reflecting layer comprises aluminum oxide.

9. The image sensor of claim 1, further comprising a passivation layer disposed on the second rear anti-reflecting layer.

10. The image sensor of claim 9, wherein the passivation layer comprises aluminum oxide.

11. An image sensor comprising:
a first pixel;
a second pixel spaced apart from the first pixel in a first lateral direction;
a third pixel spaced apart from the first pixel in a second lateral direction;
a fourth pixel spaced apart from the second pixel in the second lateral direction and spaced apart from the third pixel in the first lateral direction;
a first rear anti-reflecting layer disposed on the first pixel, the second pixel, the third pixel, and the fourth pixel;
a support barrier metal pattern disposed on the first rear anti-reflecting layer between the first pixel and the fourth pixel;
a fence disposed on the support barrier metal pattern; and
a second rear anti-reflecting layer disposed on the first rear anti-reflecting layer and the fence,
wherein an air gap is present between the first rear anti-reflecting layer and the fence and,
wherein the air gap is surrounded by the second rear anti-reflecting layer.

12. The image sensor of claim 11, wherein the air gap surrounds the support barrier metal pattern.

13. The image sensor of claim 11, wherein the support barrier metal pattern comprises titanium.

14. The image sensor of claim 11, wherein the air gap extends between the first pixel and the second pixel, between the first pixel and the third pixel, between the second pixel and the fourth pixel, and between the third pixel and the fourth pixel.

15. An image sensor comprising:
a first pixel;
a second pixel spaced apart from the first pixel in a first lateral direction;
a third pixel spaced apart from the first pixel in a second lateral direction;
a fourth pixel spaced apart from the second pixel in the second lateral direction and spaced apart from the third pixel in the first lateral direction;
a pixel isolation structure between the first pixel and the second pixel, between the first pixel and the third pixel, and between the third pixel and the fourth pixel;
a first aluminum oxide layer disposed on the first pixel, the second pixel, the third pixel, the fourth pixel, and the pixel isolation structure;
a hafnium oxide layer disposed on the first aluminum oxide layer;
a titanium pattern disposed on the hafnium oxide layer, wherein the titanium pattern extends between the first pixel and the fourth pixel;
a titanium nitride layer disposed on the titanium pattern;
a low refractive-index fence disposed on the titanium nitride layer;
a silicon oxide layer disposed on the hafnium oxide layer and the low refractive-index fence; and
a second aluminum oxide layer disposed on the silicon oxide layer,
wherein an air gap is present between the hafnium oxide layer and the titanium nitride layer,
wherein the air gap is surrounded by the silicon oxide layer, and
wherein the air gap surrounds the titanium pattern.

16. The image sensor of claim 15, wherein a width of the titanium pattern is in a range of about 5 nm to about 10 nm.

17. The image sensor of claim 15, wherein a height of the titanium pattern is in a range of about 50 nm to about 70 nm.

18. The image sensor of claim 15, wherein a thickness of the silicon oxide layer on the hafnium oxide layer is greater than a thickness of the silicon oxide layer on a side surface of the low refractive-index fence.

19. The image sensor of claim 15, wherein a thickness of the silicon oxide layer on the hafnium oxide layer is in a range of about 50 nm to about 100 nm.

20. The image sensor of claim 15, wherein a thickness of the silicon oxide layer on a side surface of the low refractive-index fence is in a range of about 5 nm to about 30 nm.
